(19) United States
(12) Patent Application Publication
(10) Pub. No.: US 2010/0193885 A1
(43) Pub. Date: Aug. 5, 2010

(54) CONDENSER MICROPHONE

(76) Inventors: Yun-Jai Choo, Incheon (KR); Kyung-Ho Kim, Anyang (KR)

Correspondence Address: David A. Einhorn, Esq.;Baker & Hostetler LLP, 45 Rockefeller Plaza, New York, NY, 10111, US

(21) Appl. No.: 12/602,524

(22) PCT Filed: Apr. 3, 2008
(86) PCT No.: PCT/KR2008/001865

§ 371 Date: Dec. 1, 2009

(30) Foreign Application Priority Data
Jun. 4, 2007 (KR) 10-2007-0054482

(51) Int. Cl. H01L 29/84

(52) U.S. Cl. 257/416; 257/E29.324

(57) ABSTRACT

Provided is a condenser microphone that can reduce the size of a product by disposing a support member over a sound hole of a PCB and mounting a chip on the support member. The condenser microphone includes a micro electro mechanical system (MEMS) chip converting a sound into an electrical signal, a substrate including a sound hole through which the sound is introduced, the MEMS chip being mounted to the substrate, a support member over the sound hole, and a semiconductor chip processing the electrical signal converted through the MEMS chip.

### TECHNICAL FIELD

The present invention relates to a condenser microphone that can reduce the size of a product by disposing a support member over a sound hole of a printed circuit board (PCB) and mounting a chip on the support member.

### BACKGROUND ART

Recently, very common multimedia devices, e.g., camcorders, moving picture experts croup layer 3s (MP3s) and mobiles generally include a function of recording sound in surroundings.

Particularly, since miniaturized microphones are mounted in miniaturized and integrated multimedia devices, such a recording function can be normally performed in the multimedia devices with maintaining a high performance.

Such microphones are classified into an electrodynamic microphone using a magnet, and a condenser microphone using the principle of a condenser (or capacitor).

Such an electrodynamic microphone, employing an induced electromotive force, includes a magnet and a coil. The magnet forms a predetermined magnetic field in the electrodynamic microphone. The coil is connected to a diaphragm plate and movable in the magnetic field. In the electrodynamic microphone, the induced electromotive force, generated when the coil is shaken in the magnetic field by vibrations, is measured and converted into an electrical signal.

The electrodynamic microphone is mechanically solid, so that can be used in poor surroundings. However, since the electrodynamic microphone should have the magnet, miniaturization is difficult, and sensitivity characteristics are poor, and a response speed is low.

On the other hand, for such condenser microphones, widely used in mobile communication terminals or audio systems, miniaturization is relatively convenient, and sensitivity characteristics and a response speed are higher. In the condenser microphone, a magnetic filed is generated through a diaphragm plate and a backplate, and variations in the magnetic field through vibrations of the diaphragm plate is measured and converted into an electrical signal.

To this end, power should be supplied to any one of the diaphragm plate and the backplate to form a magnetic field. Thus, a method of supplying power to the backplate has been used, and recently, a condenser microphone without additional power has been developed using electret exhibiting electric charge storage.

It is possible to miniaturize such condenser microphones by using electret having a quasi-permanent electric charge. The condenser microphone using electret is referred to as an electret condenser microphone (hereinafter, referred to as a ‘ECM’), which is classified into a front-type, a back-type, and a foil-type that a diaphragm plate also serves as electret, depending on the positions of electret and a diaphragm plate.

Such an ECM is manufactured in a structure that a diaphragm plate, a dielectric plate, a spacer ring, insulating and conductive base rings, and a PCB are sequentially stacked in a cylindrical or polygonal container (or case) having a closed surface. Also, a sound hole is disposed in the closed surface of the cylindrical or polygonal container, and vibrations generated by a voice are transmitted through the sound hole.

In addition, the diaphragm plate, the dielectric plate, the spacer ring, the insulating base ring, and the conductive base ring are stored in the case, the remainder of the case is bent and sealed, or the PCB is coupled to an end of the case to form the ECM.

A portion exposed from the PCB includes a solder ball for applying a surface mount devices (SMD) method, or a terminal for the connection to a main board or a motherboard. The ECM including the solder ball or the terminal is attached to the motherboard through an attaching process such as a SMD process or a soldering process.

Recently, a semiconductor fabrication technology with micro machining is widely used as a technology used for the integration of the micro devices. The technology, referred to as a micro electro mechanical system (MEMS), is used to manufacture a micro-level sensor or actuator and an electro mechanical structure by applying a semiconductor process, particularly, an integrated circuit technology.

MEMS chip microphones are manufactured using such a micro machining technology to achieve miniaturization, high-performance, multi-function, integration and improve stability and reliability, through high-precision micro fabrication.

However, the related art microphone has a structure that the above described components are stacked or stored on the PCB and mounted onto the main board.

Accordingly, in the case where a mobile communication terminal includes the main board, the thickness of a region in which the condenser microphone is mounted is increased. As a result, there is a limit to the slimness of a thick multimedia device including the condenser microphone.

FIG. 1 is a perspective view illustrating a condenser microphone according to a related art.

A related art PCB 10 includes a circuit and terminals for transmitting electrical signals to the outside after amplifying and filtering processes for the electrical signals caused by the change of an electric field with circuit components.

Also, an applications spec integrated circuit 20 (hereinafter, referred to as a ??ASIC??) chip and an MEMS chip 30 are disposed on the PCB 10.

A sound hole 40, for receiving a voice signal, penetrates through a portion of the PCB 10. Vibrations, generated by a voice, are transmitted to an inner circuit through the sound hole 40.

The related art rear-mount-type condenser microphone has a structure that the sound hole 40 is disposed in the PCB 10. Accordingly, chips including the ASIC chip 20 and the MEMS chip 30 should be mounted in other regions except for a position where the sound hole 40 is disposed on the PCB 10. Thus, the use of space is unfavorable in relation to the mounting of the chips.

Particularly, when an encapsulation process is performed on a semiconductor chip, a region that the semiconductor chip takes on the PCB is increased, so that the entire size of the microphone is increased. Also, when a foreign object is directly introduced through the sound hole, it is difficult to maintain good sound quality.

### DISCLOSURE

### Technical Problem

The present invention has been made in an effort to solve the above-described problems of the related art. An object of the present invention is to obtain enough space for mounting a chip and reduce the size of a product by disposing a support member over a sound hole of a PCB and mounting a chip on the support member.

### Technical Solution

To achieve the objects of the present invention, there is provided a condenser microphone including: a micro electro mechanical system (MEMS) chip converting a sound into an electrical signal; a substrate including a sound hole through which the sound is introduced, the MEMS chip being mounted to the substrate; a support member over the sound hole; and a semiconductor chip processing the electrical signal converted through the MEMS chip.

### Advantageous Effects

As described above, the present invention provides the following effects.

Firstly, enough space for mounting a chip is obtained and the size of a product is reduced, by disposing a support member over a sound hole of a PCB and mounting a chip on the support member.

Secondly, the slimness of mobile communication terminals including a condenser microphone is maximized.

### DESCRIPTION OF DRAWINGS

FIG. 1 is a perspective view illustrating a condenser microphone according to a related art.

FIG. 2 is a perspective view illustrating a condenser microphone according to an embodiment of the present invention.

FIG. 3 is a cut-away perspective view illustrating a condenser microphone according to an embodiment of the present invention.

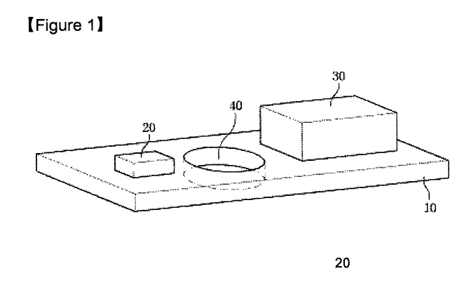

### DESCRIPTION OF THE SYMBOLS IN MAIN PORTIONS OF THE DRAWINGS

100: PCB 200: Support Member

200a: Opening 300: ASIC Chip

400: MEMS Chip 500: Sound Hole

### BEST MODE

Hereinafter, embodiments of the present invention will now be described in detail with reference to the accompanying drawings.

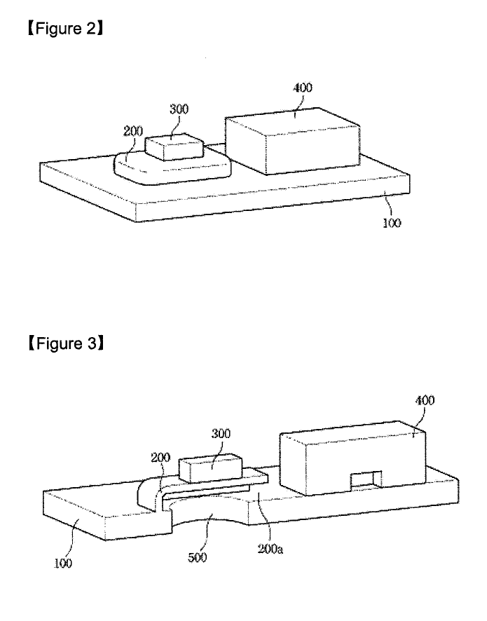

FIG. 2 is a perspective view illustrating a condenser microphone according to an embodiment of the present invention.

A printed circuit board 100 (hereinafter, referred to as a ‘PCB’) of the present invention includes a circuit and terminals for transmitting electrical signals to the outside after amplifying and filtering processes for the electrical signals caused by the change of an electric field with circuit components.

A support member 200 and a micro electro mechanical system (MEMS) chip 400 are disposed on the PCB 100. In addition, an applications spec integrated circuit 300 (hereinafter, referred to as an ‘ASIC’) chip 300 is further disposed on the support member 200.

Although the area of the ASIC chip 300 is smaller than that of the support member 200 in this embodiment, the area of the support member 200 may be the same as that of the ASIC chip 300 and is not limited to a certain size.

Also, although the ASIC chip 300 is exemplified as a semiconductor chip in this embodiment, it is not limited thereto. The circuit component corresponds to an electronic circuit unit formed through a semiconductor process, which may include, e.g., a typical FET or IC.

The support member 200 with an open side has a tetragonal shape to entirely cover a sound hole formed in the PCB 100.

Although the tetragonal container-type support member 200 having the open side is exemplified in this embodiment, the present invention is not limited thereto. The support member 200 may have a cylindrical shape, or be formed in a way similar to the contours of chip parts in consideration of the shapes of the chip parts.

That is, the shape of the support member 200 may vary depending on the shapes of the circuit components. For example, in the case where the circuit components have cylindrical shapes, the shape of the support member 200 may have a cylindrical shape, and in the case where the circuit components have cubic shapes, the shape of the support member 200 may have a cubic shape.

Also, the support member 200 may be formed of any one of brass, copper, stainless steel, and nickel alloy to shield noise and improve electric conductivity and prevent corrosion. The material of the support member 200 is not limited thereto, and any conductive metal material can be used for the support member 200.

FIG. 3 is a cut-away perspective view illustrating a condenser microphone according to an embodiment of the present invention.

A sound hole 500, for receiving a voice signal, penetrates through a portion of the PCB 100. Vibrations, generated by a voice, are transmitted to an inner circuit through the sound hole 500. The support member 200, connected to the sound hole 500, is hollowed and has an extended shape with a predetermined length.

A top of the support member 200 connected to the ASIC chip 300, is closed to prevent the direct introduction of a foreign object to a chip. Accordingly, the support member 200 shields electromagnetic wave noise introduced from the outside to effectively perform an electrical signal conversion for sound. The support member 200 and the ASIC chip 300 may be attached to each other through a conductive epoxy material. The support member 200 has an opening 200a for opening the side adjacent to the MEMS chip 400. The opening 200a, disposed on the side of the support member 200, communicates with the sound hole 500. A voice signal introduced from the sound hole 500 is transmitted to the inner circuit through the opening 200a. The support member 200 has a closed structure except for the opening 200a.

A lower connection surface of the support member 200 is connected to the PCB 100 disposed around the sound hole 500 through a surface mount technology (SMT) method. That is, a solder is applied to a desired position of the PCB 100 using a metal mask, and the support member 200 in reel packing is mounted onto the PCB 100 using equipment.

The lower connection surface of the support member 200 is connected to a ground of the PCB 100. The support member 200 may be disposed on any location including both sides or a middle portion of the PCB 100, depending on the position of the sound hole 500.

Although the support member 200 mounted to the PCB 100 through the SMT method is exemplified in this embodiment, a method of mounting the support member 200 is not limited thereto. For example, the support member 200 may be connected to the PCB 100 through an epoxy material.

The MEMS chip 400 converts a voice signal provided through the sound hole 500 disposed in the PCB 100 into an electrical signal by applying the voice signal to variations in capacitance. That is, the MEMS chip 400 converts a voice signal into an electrical signal through detecting variations in capacitance according to the vibrations of a diaphragm generated by introduced sound waves. The MEMS chip 400 has a structure that a backplate is disposed on a silicon wafer using an MEMS technology and then a diaphragm is disposed with a spacer therebetween.

The ASIC chip 300 is connected to the MEMS chip 400 to process electrical signals. The ASIC chip 300 includes a voltage pump and a buffer IC. The voltage pump provides a voltage to be applied to the MEMS chip 400 such that the MEMS chip 400 operates as a condenser microphone. The buffer IC amplifies electrical signals of the MEMS chip 400.

In the buffer IC, electrical sound signals detected through the MEMS chip 400 are amplified or matched to provide the amplified or matched signals to the outside through a connection terminal. The voltage pump may be a DC-DC converter, and the buffer IC may be an analog amplifier or analog digital converter (ADC).

Although embodiments have been described with reference to a number of illustrative embodiments thereof, it should be understood that numerous other modifications, variations, replacements, and additions can be devised by those skilled in the art, which will fall within the sprit and scope of the following claims.

1. A condenser microphone comprising:
a micro electro mechanical system (MEMS) chip converting a sound into an electrical signal;
a substrate including a sound hole through which the sound is introduced, the MEMS chip being mounted to the substrate;
a support member over the sound hole; and
a semiconductor chip processing the electrical signal converted through the MEMS chip.

2. The condenser microphone of claim 1, wherein the semiconductor chip is disposed on the support member.

3. The condenser microphone of claim 2, wherein the support member is connected to the semiconductor chip through an epoxy material.

4. The condenser microphone of claim 1, wherein the support member has a container-type structure entirely covering the sound hole.

5. The condenser microphone of claim 1, wherein the support member is hollowed and have an extended shape with a predetermined length.

6. The condenser microphone of claim 1, wherein the support member comprises a closed top.

7. The condenser microphone of claim 1, wherein the support member comprises an open side to provide an opening.

8. The condenser microphone of claim 7, wherein the opening of the support member is disposed in a side adjacent to the MEMS chip.

9. The condenser microphone of claim 7, wherein the opening communicates with the sound hole.

10. The condenser microphone of claim 1, wherein the support member is disposed on the substrate through a surface mount technology (SMT) method.

11. The condenser microphone of claim 1, wherein the support member is connected to the substrate through an epoxy material.

12. The condenser microphone of claim 1, wherein the support member has the same shape as that of the semiconductor chip.

13. The condenser microphone of claim 1, wherein the support member is firmly attached to an edge on a side of the sound hole.

14. The condenser microphone of claim 1, wherein the semiconductor chip comprises an applications spec integrated circuit (ASIC) chip.

15. The condenser microphone of claim 1, wherein the substrate comprises a printed circuit board (PCB).

16. The condenser microphone of claim 1, wherein the semiconductor chip has an area smaller than that of the support member.

17. The condenser microphone of claim 1, wherein the support member is formed of a conductive metal.

18. The condenser microphone of claim 4, wherein the support member is hollowed and have an extended shape with a predetermined length.

19. The condenser microphone of claim 4, wherein the support member comprises a closed top.

20. The condenser microphone of claim 4, wherein the support member comprises an open side to provide an opening.

21. The condenser microphone of claim 20, wherein the opening of the support member is disposed in a side adjacent to the MEMS chip.

22. The condenser microphone of claim 20, wherein the opening communicates with the sound hole.
